(19) United States
(12) Patent Application Publication
(10) Pub. No.: US 2016/0143183 A1
(43) Pub. Date: May 19, 2016

(54) ELECTRONIC APPARATUS

(71) Applicant: Seiko Epson Corporation, Tokyo (JP)

(72) Inventors: Katsunori Tanaka, Azumino-shi (JP); Yuji Kajihara, Matsumoto-shi (JP); Masatoshi Tanaka, Azumino-shi (JP)

(21) Appl. No.: 14/931,467

(22) Filed: Nov. 3, 2015

(30) Foreign Application Priority Data
Nov. 13, 2014 (JP) 2014-230439

(51) Int. Cl. H05K 7/20; H04N 9/31

(52) U.S. Cl. CPC H05K 7/20172; H05K 7/20145; H04N 9/3144

(57) ABSTRACT

An electronic apparatus (for example, a projector) includes a cooling fan, a fixation frame that fixes the cooling fan, and an external housing that fixes the fixation frame. The fixation frame includes a plate-shaped portion that fixes the cooling fan. The plate-shaped portion has one end fixed to the external housing and the other end which is released, is installed so as to be substantially perpendicular to an extending direction of a rotation center axis of the cooling fan, and has flexibility that the plate-shaped portion is bent in a substantially extending direction of the rotation center axis when an impact is applied to the electronic apparatus.

### BACKGROUND

1. Technical Field

The present invention relates to an electronic apparatus.

2. Related Art

Hitherto, there have been known electronic apparatuses including a cooling fan for cooling a component that internally generates heat. As the electronic apparatus, for example, there is known a projector that modulates light (emitted light) emitted from a light source by an optical modulation device in accordance with image information and projects the modulated light.

Such a projector also includes a cooling fan. The projector cools an optical component, such as a light source or an optical modulation device which is warmed by light emitted from the light source, using a cooling fan. In general, the cooling fan cools the optical component by suctioning the open air, making the suctioned open air flow through a duct, and discharging the open air so as to be blown against the optical component, thereby making the optical component radiate heat. In addition, as the cooling fan, a fan that exhausts warmed air within a housing to the outside of the housing is also used.

In a duct fan unit disclosed in JP-A-2003-166497, a duct through which an air flow passes is constituted by a pair of first duct components and a fan, and the fan is installed by providing a rib-like guide in only one first duct component. The other first duct component is provided with an elastic protrusion that elastically presses a fan during assembling. Both of the first duct components are fixed only by locking using a locking piece and a locking hole and have a fan being inserted thereinto and pressed with an elastic protrusion. With such a configuration, provided is a duct fan unit that has a simple structure, has high workability during the attachment and detachment thereof, and is capable of being manufactured at a low cost.

When a drop test is performed on an electronic apparatus (for example, a projector) which includes a cooling fan as a quality evaluation test, particularly, when a drop test in which an air suction port of the cooling fan faces downward is performed, a problem in that the cooling fan malfunctions within a guarantee standard of a product due to an impact of a drop may occur.

Therefore, in an electronic apparatus including a cooling fan, there have been demands for an electronic apparatus with a reduced influence on a cooling fan due to an impact of a drop.

### SUMMARY

An advantage of some aspects of the invention is to solve at least a part of the problems described above, and the invention can be implemented as the following forms or application examples.

### Application Example 1

This application example is directed to an electronic apparatus including a cooling fan, a fixation frame that fixes the cooling fan, and an external housing that fixes the fixation frame. The fixation frame includes a plate-shaped portion that fixes the cooling fan. The plate-shaped portion has one end fixed to the external housing and the other end which is released, is installed so as to be substantially perpendicular to an extending direction of a rotation center axis of the cooling fan, and has flexibility that the plate-shaped portion is bent in a substantially extending direction of the rotation center axis when an impact is applied to the electronic apparatus.

According to the electronic apparatus, the plate-shaped portion having fixed the cooling fan can be configured to have a structure of a substantially cantilever. When the projector drops in a drop direction which is substantially perpendicular to the plate-shaped portion as a predetermined drop direction (direction in which an impact is applied), the plate-shaped portion is bent in the drop direction, and thus it is possible to absorb an impact applied to the cooling fan by the drop. Thereby, it is possible to realize the electronic apparatus with a reduced influence on the cooling fan due to an impact of a drop in the electronic apparatus including the cooling fan.

### Application Example 2

In the electronic apparatus according to the application example, it is preferable that the cooling fan is fixed to the plate-shaped portion by a first screw which is inserted in a direction substantially parallel to the rotation center axis.

According to the electronic apparatus with this configuration, the cooling fan is fixed to the plate-shaped portion by the first screw which is inserted in a direction substantially parallel to the rotation center axis. Thereby, an impact of a drop is directly propagated to the plate-shaped portion, and the plate-shaped portion is shaken due to an impact, and thus it is possible to reduce an influence on the cooling fan due to the impact of the drop.

### Application Example 3

In the electronic apparatus according to the application example, it is preferable that the plate-shaped portion has an extension portion extending from the one end and the extension portion includes a plurality of hole portions for performing fixation to the external housing by a screw along the one end.

According to the electronic apparatus with this configuration, the plurality of hole portions of the extension portion are installed along the one end of the plate-shaped portion, and thus there is a tendency for the plate-shaped portion to be further bent, which makes it easier to absorb an impact of a drop. Therefore, it is possible to further reduce an influence on the cooling fan due to the impact.

### Application Example 4

In the electronic apparatus according to the application example, it is preferable that the fixation frame constitutes a portion of a duct that makes air suctioned by the cooling fan flow.

According to the electronic apparatus with this configuration, a fixation frame constitutes a portion of a duct, and thus it is possible to cool a component generating heat by making the air suctioned by the cooling fan flow.

### Application Example 5

It is preferable that the electronic apparatus according to the application example further includes a light source device that emits light, an optical modulation device that modulates the light emitted from the light source device in accordance with image information, and a projection lens that projects the light modulated by the optical modulation device.

According to the electronic apparatus with this configuration, it is possible to exhibit effects of the above-mentioned application examples with respect to a so-called projector in which a light source device emits light, an optical modulation device modulates the emitted light in accordance with image information, and a projection lens projects the modulated light as image light.

### BRIEF DESCRIPTION OF THE DRAWINGS

The invention will be described with reference to the accompanying drawings, wherein like numbers reference like elements.

FIG. 1 is a schematic diagram illustrating an optical unit and a cooling mechanism of a projector according to an embodiment.

FIG. 2 is a perspective view illustrating the cooling mechanism installed in an external housing.

FIG. 3 is a perspective view illustrating the cooling mechanism and the external housing which are separated from each other.

FIG. 4 is an exploded perspective view of the cooling mechanism.

FIG. 5 is an exploded perspective view of the cooling mechanism.

FIG. 6 is a perspective view in a state where the cooling mechanism is vertically inverted.

FIG. 7 is a perspective view of the cooling mechanism.

### DESCRIPTION OF EXEMPLARY EMBODIMENTS

Hereinafter, an embodiment will be described with reference to the accompanying drawings.

### EMBODIMENT

The present embodiment relates to a projector 1 as an electronic apparatus to which the invention is applied.

The projector 1 of the present embodiment is a device that modulates light emitted from a light source device 31 by liquid crystal panels 351 (optical modulation devices) in accordance with image information and projects the modulated light from a projection lens 36 as image light.

Outlines of Configurations and Operations of Optical Unit 3 and Cooling mechanism 4

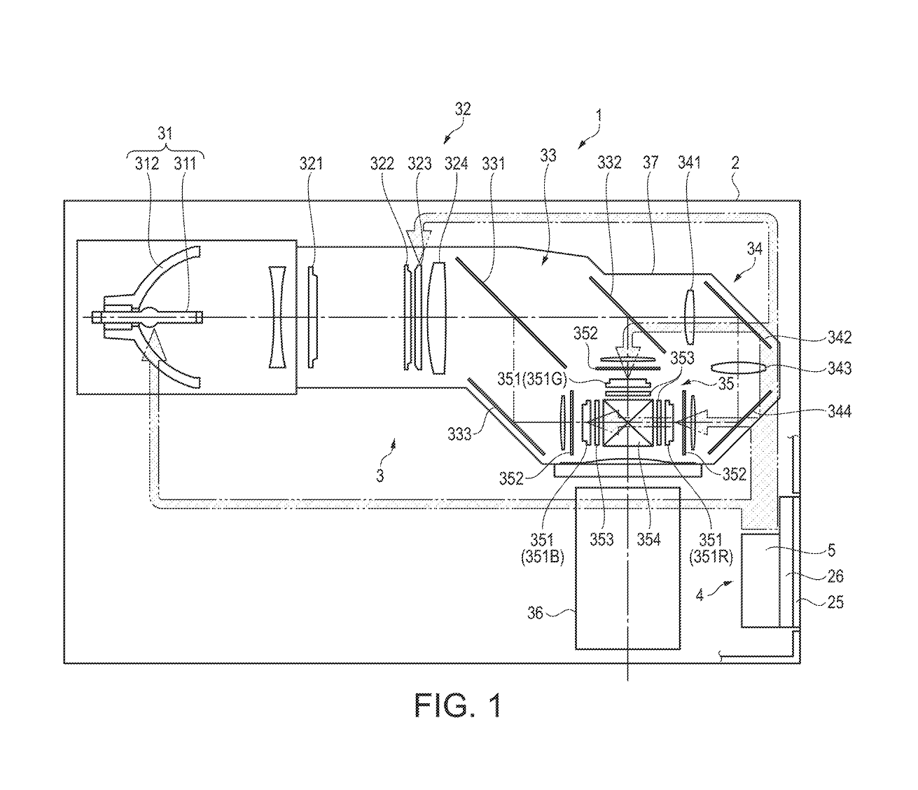

FIG. 1 is a schematic diagram illustrating an optical unit 3 and a cooling mechanism 4 of the projector 1. The optical unit 3 operates under the control of a control unit (not shown) and forms image light in accordance with image information. As illustrated in FIG. 1, the optical unit 3 includes a light source device 31 including a light source lamp 311 and a reflector 312, and an illumination optical device 32 including lens arrays 321 and 322, a polarization conversion element 323, and a superimposing lens 324. In addition, the optical unit 3 includes a color dividing optical device 33 including dichroic mirrors 331 and 332 and a reflecting mirror 333, and a relay optical device 34 including an incidence-side lens 341, a relay lens 343, and reflecting mirrors 342 and 344.

In addition, the optical unit 3 includes an optical device 35 including three liquid crystal panels 351 as optical modulation devices (a liquid crystal panel for red (R) right is denoted by 351R, a liquid crystal panel for green (G) right is denoted by 351G, and a liquid crystal panel for blue (B) right is denoted by 351B), three incidence-side polarizing plates 352, three emission-side polarizing plates 353, and a cross dichroic prism 354 as a color synthesis optical device. In addition, the optical unit 3 includes a projection lens 36 as a projection optical device, and a housing 37 for an optical component which accommodates each optical device.

According to the above-mentioned configuration, the optical unit 3 divides a luminous flux which is emitted from the light source device 31 and passes through the illumination optical device 32 into three color light beams of R light, G light, and B light by the color dividing optical device 33. In addition, the divided color light beams are modulated by the respective liquid crystal panels 351 in accordance with image information to be formed as modulated light beams for the respective color light beams. The modulated light beams for the respective color light beams are incident on the cross dichroic prism 354 and are synthesized as image light, and are enlarged and projected on a screen (not shown) or the like through the projection lens 36. Meanwhile, the optical devices 31 to 36 are used as optical systems of various general projectors, and thus a detailed description thereof will not be repeated.

The cooling mechanism 4 is a mechanism that introduces the open air into the external housing 2 and cools the external housing with respect to an optical device that generates heat by the optical unit 3 or an optical component constituting the optical device. As illustrated in FIG. 1, an open air introducing port 25 that introduces the open air into the external housing 2 is installed on the side surface of the external housing 2, and a filter 26 that prevents from the infiltration of dust is installed therein.

The cooling mechanism 4 suctions the open air into the cooling fan 5 through the open air introducing port 25 and the filter 26 by the driving of the cooling fan 5. The suctioned open air is discharged by the cooling fan 5. The discharged open air flows to the vicinity of an optical component required to be cooled, as indicated by a two-dot chain line, through a duct (not shown in FIG. 1), and is discharged from a discharge port of the duct. The discharged open air is cooled by being blown against the optical component, which is required to be cooled, to deprive the heat of the optical component. In the present embodiment, the cooling mechanism 4 cools the optical device 35 (particularly, the liquid crystal panels 351 and the emission-side polarizing plates 353), the polarization conversion element 323, and the light source device 31.

Although not shown in the drawing, the cooling mechanism 4 exhausts the air within the external housing 2, which deprives heat from a heat generating component and is warmed, to the outside of the external housing 2 (to the outside of the projector 1) using an exhaust fan. By such a series of operations of the cooling mechanism 4, it is possible to appropriately control the temperature of components constituting the projector 1, including an optical component, a circuit block, a power supply block, and the like. The configuration of the cooling mechanism 4 will be described later.

### Configuration and Operation of Cooling Mechanism 4

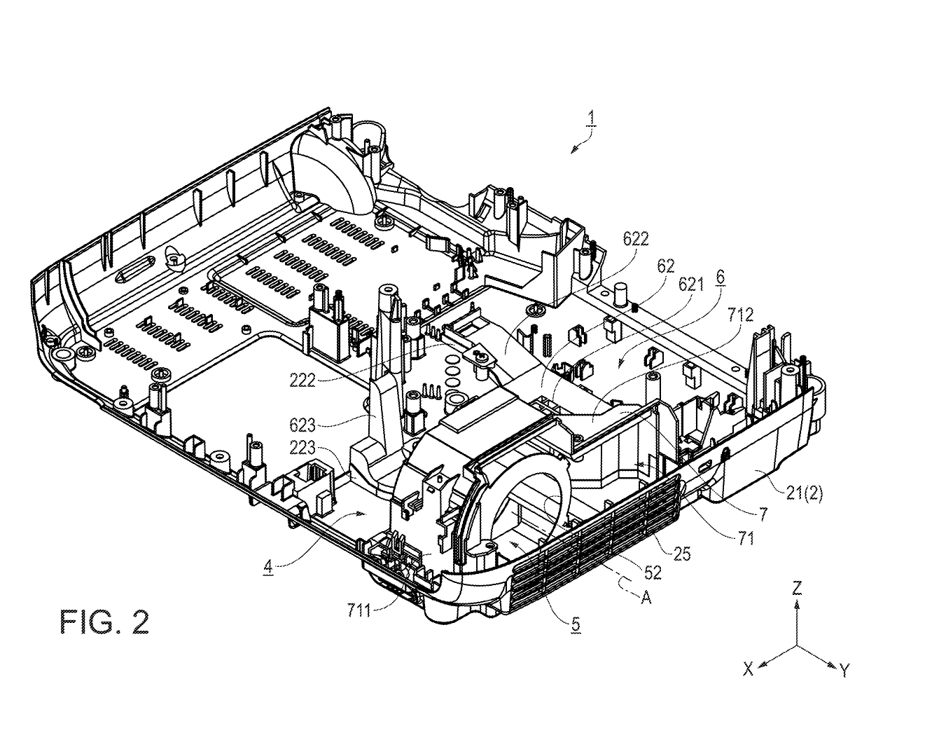

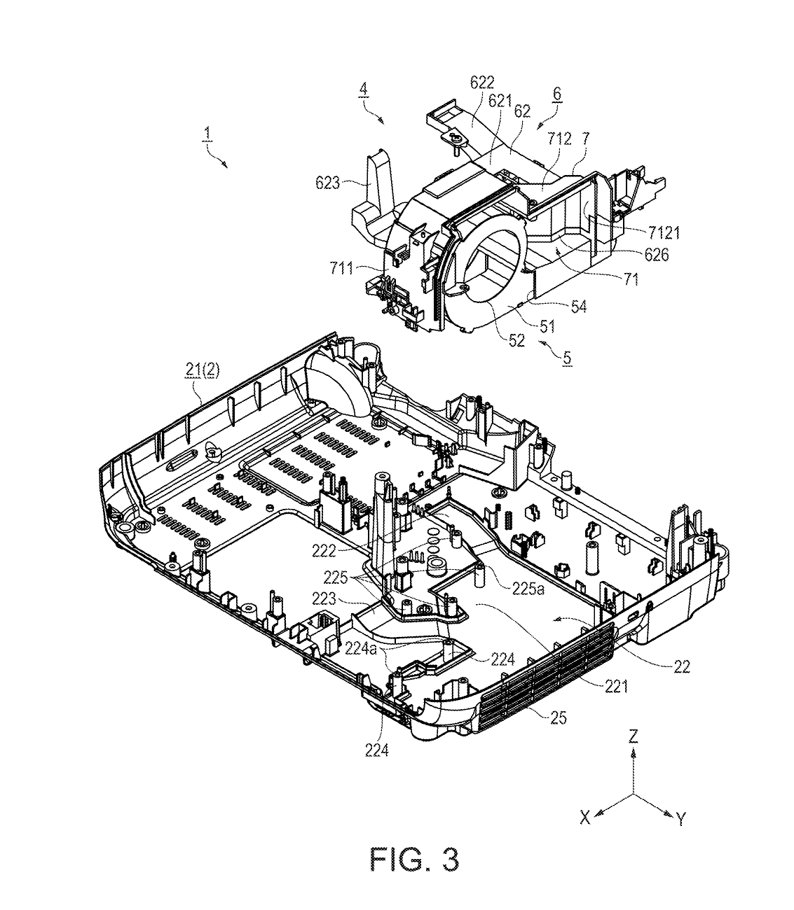

FIG. 2 is a perspective view illustrating the cooling mechanism 4 installed in the external housing 2. FIG. 3 is an exploded perspective view illustrating the cooling mechanism 4 and the external housing 2. In FIGS. 2 and 3 and the subsequent drawings, an XYZ orthogonal coordinate system is used for convenience of description. Although not shown in the drawing, in the XYZ orthogonal coordinate system, a projection direction of the projection lens 36 is assumed to be an X(+) direction, and a direction of the open air introducing port 25 which is perpendicular to the X direction is assumed to be a Y(+) direction. In addition, an upper direction which is perpendicular to the X direction and the Y direction in a posture in which the projector 1 is installed on a desk is assumed to be a Z(+) direction. In addition, the XYZ orthogonal coordinate system is appropriately used on the assumption that the X(+) direction is a front direction (front side), an X(−) direction is a rear direction (rear side), the Y(+) direction is a right direction (right side), a Y(−) direction is a left direction (left side), the Z(+) direction is an upper direction (upper side), and a Z(−) direction is a lower direction (lower side).

FIGS. 2 and 3 illustrate only main components among components constituting the projector 1. As the main components, a lower case 21 constituting the external housing 2 and the cooling mechanism 4 fixed to the lower case 21 are shown. Meanwhile, the external housing 2 is formed to have a substantially flat hexahedral shape in the present embodiment. The external housing 2 is constituted not only by the lower case 21 but also by an upper case, a front case, a rear case (all of which are not shown in the drawing), and the like.

As illustrated in FIGS. 2 and 3, the open air introducing port 25 having a plurality of slit-shaped holes, serving as introducing ports when the cooling fan 5 suctions the open air, is installed on the side surface of the lower case 21 in the right front direction. The open air introducing port 25 is also installed in the same region of the upper case not shown in the drawing. In addition, the filter 26 which is detachably provided and removes dust included in the open air introduced from the open air introducing port 25 is installed in a region opposite to the open air introducing port 25 on the inner side of the open air introducing port 25 (inner side of the external housing 2).

The cooling mechanism 4 is installed at a corner portion of the projector 1 (lower case 21) in the right front direction so that an air suction port 52 of the cooling fan 5 faces the filter 26. The cooling mechanism 4 is roughly constituted by the cooling fan 5, a first fixation frame 6 as a fixation frame for fixing the cooling fan 5, and a second fixation frame 7 which covers a portion of the cooling fan 5 and is installed in the first fixation frame 6.

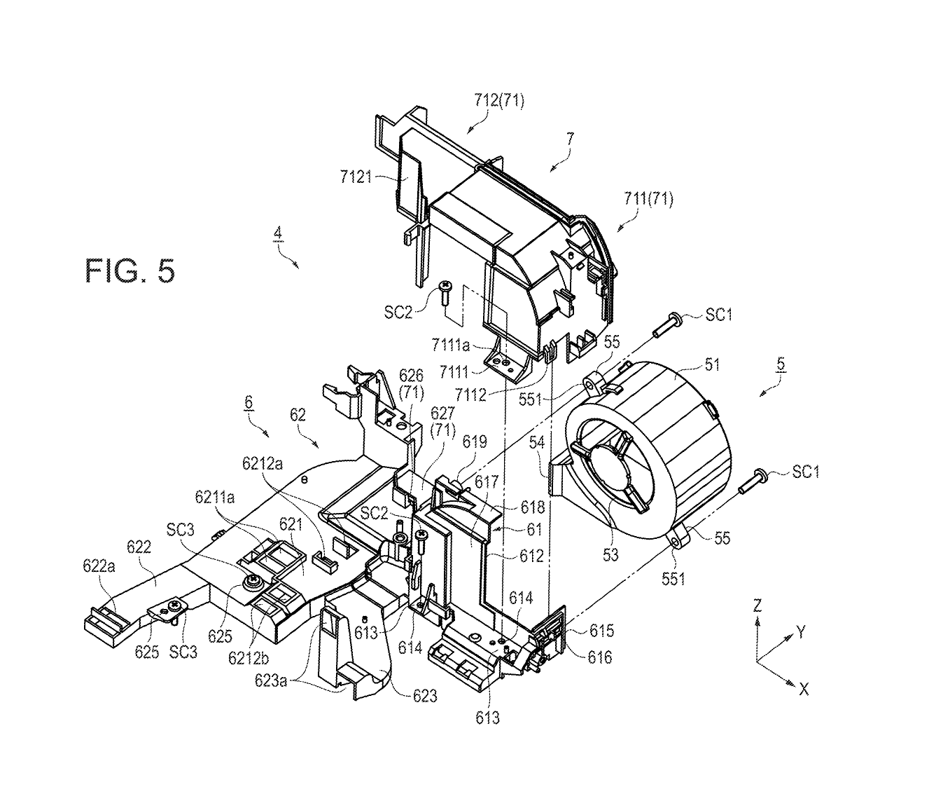

In the present embodiment, a so-called sirocco fan is used as the cooling fan 5. The sirocco fan is a fan that discharges the air (open air) suctioned from a direction of a rotation axis in a direction of a centrifugal force by rotation. In the cooling fan 5, a driving system (not shown) such as an impeller is installed within a main body 51 having a substantially columnar shape, and a first air suction port 52 that suctions the open air is formed on a surface of the main body 51 which is substantially perpendicular to a direction of a rotation center axis A. In addition, in the cooling fan 5 of the present embodiment, a second air suction port 53 (FIG. 5) is also formed on an opposite surface of the main body 51 which is opposite to the air suction port 52, and the open air is suctioned from the air suction port 53. The first air suction port 52 serves as a main air suction port, and the second air suction port 53 serves as a sub-air suction port. The air suction port 52 is installed so as to face the filter 26. In addition, the main body 51 is provided with a discharge port 54 (FIG. 3) that discharges the suctioned open air in a direction of a centrifugal force.

The cooling fan 5 operates to suction the open air from the air suction port 52 through the open air introducing port 25 and the filter 26. In addition, the cooling fan also suctions the open air from the air suction port 53. The cooling fan discharges the suctioned open air from the discharge port 54. Meanwhile, in FIGS. 2 and 3, the filter 26 positioned between the open air introducing port 25 and the air suction port 52 is not shown in the drawing.

The first fixation frame 6 fixes the cooling fan 5 and constitutes a portion of a duct that makes the open air flow into an optical component required to be cooled. Meanwhile, the duct is configured such that a portion of the duct is also formed at a position corresponding to the duct of the first fixation frame 6 in the lower case 21 and the duct capable of making the open air flow therethrough is formed by installing the first fixation frame 6 at a predetermined position of the lower case 21. In addition, the second fixation frame 7 is positioned over the first fixation frame 6, covers the cooling fan 5, and constitutes a duct that makes the open air suctioned through the filter 26 flow into the second air suction port 53 together with the first fixation frame 6.

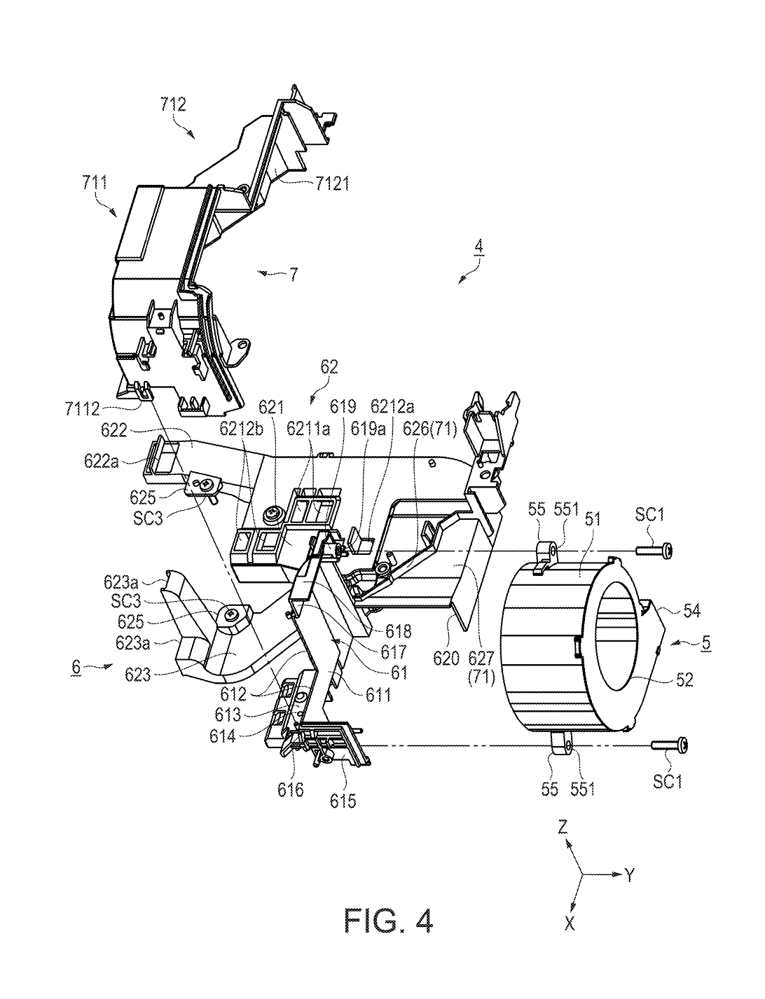

FIGS. 4 and 5 are exploded perspective views of the cooling mechanism 4. In detail, FIG. 4 is an exploded perspective view when the right side of the cooling mechanism 4 is seen from an upper direction, and FIG. 5 is an exploded perspective view when the cooling mechanism 4 of FIG. 4 is seen from the opposite direction.

### Configurations of Cooling Fan 5 and First Fixation Frame 6

In the cooling fan 5, two fixation portions 55 having a hole portion 551 are formed on the side surface of the main body 51, and a first screw SC1 is inserted into the hole portion 551 at the time of fixing the cooling fan 5. The first fixation frame 6 is formed to include a plate-shaped portion 61 that fixes the cooling fan 5 and is formed to have a substantially plate shape, and a duct component 62 which is connected to the rear side of one end 611 which is a lower side of the plate-shaped portion 61 to constitute a duct (a portion of a duct).

The plate-shaped portion 61 includes a notch portion 612 which is positioned on the left side of the sub-air suction port 53 of the cooling fan 5 and partially exposes the air suction port 53. The one end 611 serving as a lower end of the plate-shaped portion 61 is provided two extension portions 613 extending in the left direction. A hole portion 614 for fixing the plate-shaped portion 61 to the lower case 21 is formed in each of the two extension portions 613, and a second screw SC2 for fixation is inserted into the hole portion 614 at the time of fixation. Meanwhile, the two hole portions 614 are formed along the one end 611 in the vicinity of the one end 611.

A wall portion 615 extending in the right direction is formed on the front side of the one end 611 (front side of the notch portion 612), and a fixation portion (same as a fixation portion 619 to be described later) for fixing the cooling fan 5 is formed on the rear side of the wall portion 615. In addition, a protrusion portion 616 for locking the second fixation frame 7 is formed on the front side of the wall portion 615.

The other end 617 which is an upper end of the plate-shaped portion 61 and is opposite to the one end 611 is provided with a cover portion 618 which extends in the right direction and covers a portion of an upper portion of the main body 51 of the cooling fan 5. The fixation portion 619 for fixing the cooling fan 5 is formed on the rear side of the cover portion 618 so as to protrude in the right direction. Meanwhile, the cooling fan 5 is fixed to the plate-shaped portion 61 by making two fixation portions 55 of the cooling fan 5 abut on the two fixation portions 619 of the plate-shaped portion 61 from the right direction and screwing the fixation portions into screw holes 619a of the fixation portions 619 by the first screws SC1.

### Configuration of Duct Component 62

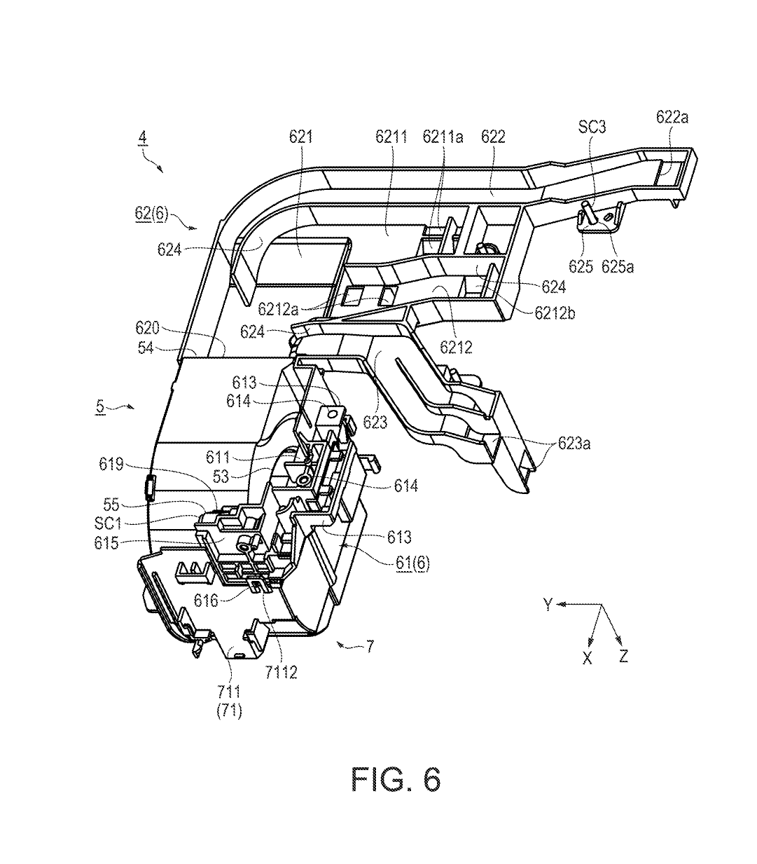

FIG. 6 is a perspective view in a state where the cooling mechanism 4 is vertically inverted. A configuration and operation of the duct component 62 will be described below with reference to FIGS. 4 to 6. The duct component 62 is a portion constituting a duct that makes the open air discharged from the discharge port 54 of the cooling fan 5 flow. In the present embodiment, the duct component 62 makes the open air discharged from the discharge port 54 of the cooling fan 5 flow in from an introducing port 620 connected to the discharge port 54 and flow into three locations required to be cooled.

In the present embodiment, the duct component 62 is constituted by a first duct 621 constituting a duct for mainly cooling the liquid crystal panels 351 and the emission-side polarizing plates 353, a second duct 622 constituting a duct for cooling the polarization conversion element 323, and a third duct 623 constituting a duct for cooling the light source device 31. Meanwhile, the duct component 62 is constituted by the three ducts 621, 622, and 623 which are combined with each other. In other words, the ducts 621, 622, and 623 are configured to be partitioned by a plurality of partition walls 624.

The first duct 621 is branched into two of a duct 6211 for a flow to the side of the liquid crystal panel 351G for G light and a duct 6212 for a flow to the side of the liquid crystal panel 351R for R light and the liquid crystal panel 351B for B light. A plurality of discharge ports 6211a are formed in the tip end of the branched duct 6211 for G light. In the branched duct 6212 for R light and B light, two discharge ports 6212a for R light are formed in a root portion, and two discharge ports 6212b for B light are formed in a tip end.

In the second duct 622, a discharge port 622a is formed in a tip end. In the third duct 623, two stepped discharge ports 623a are formed in a tip end.

### Schematic Configuration of Sub-Duct Component 22

A sub-duct component 22 (FIG. 3) configured to be opposite to the duct component 62 is formed on the inner side of the lower case 21. The sub-duct component 22 is constituted by a first sub-duct 221 corresponding to the first duct 621, a second sub-duct 222 corresponding to the second duct 622, and a third sub-duct 223 corresponding to the third duct 623.

The duct component 62 (cooling mechanism 4) is installed in the lower case 21, and thus the duct component 62 and the sub-duct component 22 engage with each other, thereby completing the manufacture of each duct. In detail, the first duct 621 and the first sub-duct 221 engage with each other, the second duct 622 and the second sub-duct 222 engage with each other, and the third duct 623 and the third sub-duct 223 engage with each other, thereby completing the manufacture of each duct.

Meanwhile, the duct component 62 is provided with a wall portion 626 which is formed on a one-step recessed surface as an upper surface thereof so as to erect corresponding to a duct portion 712 (wall portion 7121) to be described later of the second fixation frame 7. The wall portion 626 and a surface portion 627 which is surrounded by the wall portion 626 and extends to the end of the wall portion in the right direction constitute a portion of a fourth duct 71 to be described later.

### Configuration of Second Fixation Frame 7

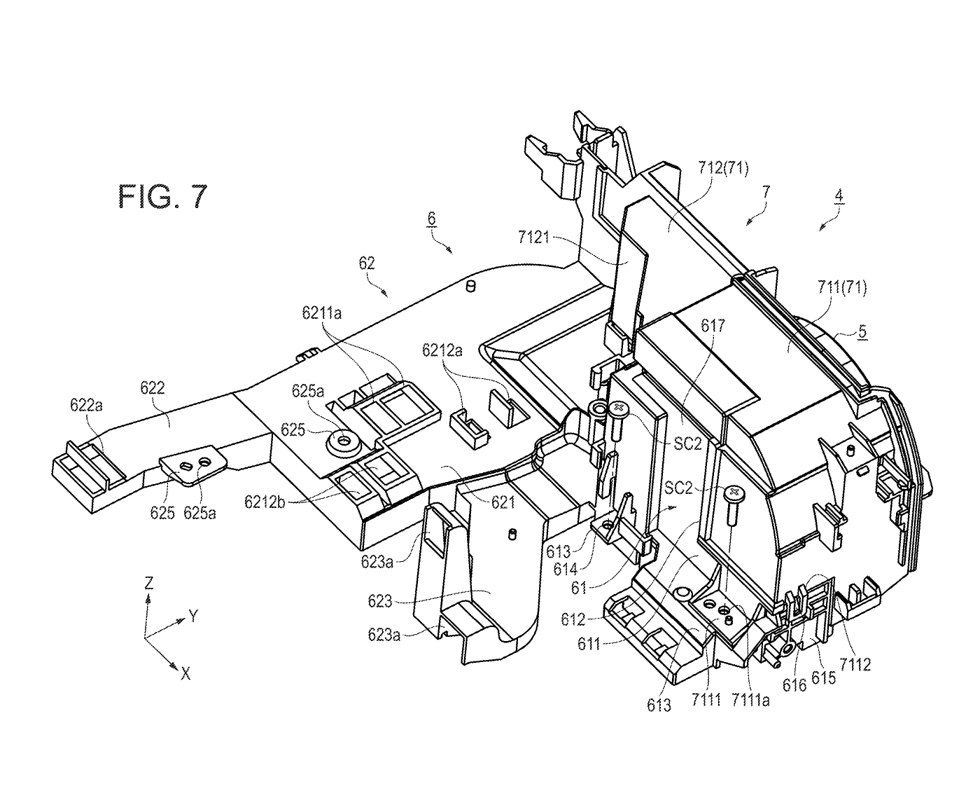

FIG. 7 is a perspective view of the cooling mechanism 4. In detail, FIG. 7 is a perspective view when the left side of the cooling mechanism 4 is seen from above. A configuration of the second fixation frame 7 will be described with reference to FIGS. 4 to 7. As described above, the second fixation frame 7 is configured as a duct component which is positioned above the first fixation frame 6, covers an upper portion of the cooling fan 5, and makes the open air suctioned through the filter 26 by the driving of the cooling fan 5 flow to the sub-air suction port 53 together with the first fixation frame 6. Meanwhile, a duct in which the second fixation frame 7 is configured as a duct component is assumed to be a fourth duct 71.

The second fixation frame 7 is provided with a cover portion 711 that covers the upper portion of the cooling fan 5 and is formed to have a shape along the outer circumference of the notch portion 612 and the wall portion 615 of the plate-shaped portion 61 to cover the cooling fan 5. As illustrated in FIG. 7, a fixation portion 7111 for fixing the second fixation frame 7 to the first fixation frame 6 is formed at a left lower end portion of the cover portion 711 so as to extend in the left direction, and is provided with a hole portion 7111a into which the second screw SC2 is inserted. In addition, a locking portion 7112 for locking the second fixation frame 7 to the first fixation frame 6 is formed on the outer surface of the cover portion 711 on the front side.

The second fixation frame 7 is provided with a duct portion 712 which is connected to the rear side of the cover portion 711 and has the right side opened so as to make the open air suctioned through the filter 26 flow. A wall portion 7121 constituting the left wall (left side surface) of the duct portion 712 engages with the wall portion 626 formed in the duct component 62 by fixing the second fixation frame 7 to the first fixation frame 6.

### Fixing of Second Fixation Frame 7 to First Fixation Frame 6

When the second fixation frame 7 is fixed to the first fixation frame 6, the second fixation frame 7 is installed from above the first fixation frame 6. In detail, the locking portion 7112 of the second fixation frame 7 is locked to the protrusion portion 616 of the first fixation frame 6. In addition, a locking portion, not shown in the drawing, of the first fixation frame 6 is locked to a protrusion portion, not shown in the drawing, which is formed on the rear side of the duct portion 712 of the second fixation frame 7. In addition, as illustrated in FIG. 7, the fixation portion 7111 formed in the second fixation frame 7 is set to abut on and overlap the top face of one of the extension portions 613 of the first fixation frame 6, and the second screw SC2 is inserted into the hole portion 7111a and the hole portion 614, thereby performing screwing to the lower case 21. Meanwhile, the screwing to the lower case 21 is performed simultaneously at the time of fixing the cooling mechanism 4 to the lower case 21.

### Fixing of Cooling Mechanism 4 to Lower Case 21

In the duct component 62, four fixation portions 625 for fixation to the lower case 21 are formed so as to have a hole portion 625a (FIGS. 6 and 7). In addition, as illustrated in FIG. 3, the lower case 21 is provided with four fixation portions 225 formed so as to protrude in response to the fixation portions 625. In addition, two protruding fixation portions 224 are formed corresponding to the hole portions 614 of two extension portions 613 of the plate-shaped portion 61.

When the cooling mechanism 4 is fixed to the lower case 21, the fixation portion 625 of the duct component 62 is made to abut on the fixation portion 225 of the lower case 21, and the extension portion 613 of the plate-shaped portion 61 is made to abut on the fixation portion 224 of the lower case 21. Next, a screw SC3 is inserted from the hole portion 625a of the fixation portion 625 to be screwed into the screw hole 225a of the fixation portion 225 of the lower case 21.

In addition, the fixation portion 7111 of the second fixation frame 7 mentioned above overlaps the upper portion of the extension portion 613 so that the second screw SC2 is inserted from the hole portion 7111a of the fixation portion 7111, is also inserted into the hole portion 614 of the extension portion 613, and is then screwed into the screw hole 224a of the fixation portion 224 of the lower case 21. Thereby, it is possible to fix the cooling mechanism 4 to the lower case 21.

The cooling mechanism 4 is fixed to the lower case 21, thereby completing the manufacture of each duct. In the present embodiment, as described above, the first duct 621, the second duct 622, and the third duct 623 are completed.

### Details of Fourth Duct 71 and Flow of Open Air

The cooling mechanism 4 is fixed to the lower case 21, and thus the fourth duct 71 has a space, which is surrounded by the duct portion 712 of the second fixation frame 7 and the wall portion 626 and the surface portion 627 of the first fixation frame 6, being formed as a duct. When the cooling fan 5 is operated, the open air flows into the space through the open air introducing port 25 and the filter 26.

In addition, the fourth duct 71 includes a connection portion between the duct portion 712 and the cover portion 711, and a space surrounded by inner surface of the plate-shaped portion 61, the inner surface of the cover portion 711, the cooling fan 5, and the sub-duct component 22 of the lower case 21 is formed as a duct. The open air having flowed in flows through the space and flows into the cooling fan 5 through the sub-air suction port 53 of the cooling fan 5.

### Flow of Open Air in Cooling Mechanism 4 (Duct Component 62)

The cooling mechanism 4 makes the open air flow into the cooling fan 5 from the main air suction port 52 through the open air introducing port 25 and the filter 26 by the driving of the cooling fan 5. The open air having flowed in is discharged from the discharge port 54, and flows into the duct component 62 through the introducing port 620 of the duct component 62. Meanwhile, the open air having flowed through the fourth duct 71 and having flowed into the cooling fan 5 from the sub-air suction port 53 is similarly discharged from the discharge port 54 and flows into the duct component 62.

The open air having flowed into the duct component 62 is branched into the ducts 621, 622, and 623 by the partition walls 624 and flows. The open air flowing through the first duct 621 is partway branched into two ducts 6211 and 6212 and flows.

The open air flowing through the duct 6211 is discharged upward from the discharge ports 6211a. Meanwhile, the discharge ports 6211a are positioned below the liquid crystal panel 351G for green light and the emission-side polarizing plate 353 for green light which constitute the optical device 35 of the optical unit 3. For this reason, the open air discharged upward from the discharge ports 6211a is set to be blown against the liquid crystal panel 351G for green light and the emission-side polarizing plate 353 for green light from below, thereby depriving heat of the liquid crystal panel 351G for green light and the emission-side polarizing plate 353 for green light which generate heat.

In addition, the open air flowing through the duct 6212 is partially discharged upward from the discharge port 6212a immediately after being branched. In addition, the remaining open air flows through the duct 6212 and is discharged upward from the discharge port 6212b. Meanwhile, the discharge port 6212a is positioned below the liquid crystal panel 351R for red light and the emission-side polarizing plate 353 for red light which constitute the optical device 35 of the optical unit 3. For this reason, the open air discharged upward from the discharge port 6212a is set to be blown against the liquid crystal panel 351R for red light and the emission-side polarizing plate 353 for red light from below, thereby depriving heat of the liquid crystal panel 351R for red light and the emission-side polarizing plate 353 for red light which generate heat.

In addition, the discharge port 6212b is positioned below the liquid crystal panel 351B for blue light and the emission-side polarizing plate 353 for blue light which constitute the optical device 35 of the optical unit 3. For this reason, the open air discharged upward from the discharge port 6212b is set to be blown against the liquid crystal panel 351B for blue light and the emission-side polarizing plate 353 for blue light from below, thereby depriving heat of the liquid crystal panel 351B for blue light and the emission-side polarizing plate 353 for blue light which generate heat.

The open air flowing through the second duct 622 is discharged upward from the discharge port 622a. Meanwhile, the discharge port 622a is positioned below the polarization conversion element 323 constituting the illumination optical device 32 of the optical unit 3. For this reason, the open air discharged upward from the discharge port 622a is set to be blown against the polarization conversion element 323 from below, thereby depriving heat of the polarization conversion element 323 that generates heat.

The open air flowing through the third duct 623 is discharged in a horizontal direction (left direction) from two stepped discharge ports 623a. Meanwhile, the discharge port 623a is positioned on the right side of the light source device 31. For this reason, the open air discharged from the discharge port 623a in the left direction is set to be blown from the right side of the light source device 31 and to flow through the light source device 31, thereby depriving heat of the light source device 31 that generates heat.

Meanwhile, as described above, the air (open air) which is warmed by cooling each optical component is exhausted to the outside of the external housing 2 through an exhaust port (not shown) by an exhaust fan not shown in the drawing. It is possible to cool a predetermined optical component that generates heat, through the above-described operation of the cooling mechanism 4.

### State of Fixed Plate-Shaped Portion 61

In a state where the cooling mechanism 4 is fixed to the lower case 21, the plate-shaped portion 61 fixes the cooling fan 5 and the extension portion 613 is set to be fixed to the lower case 21 by the second screw SC2. In other words, the one end 611 of the plate-shaped portion 61 is set to be fixed to the lower case 21. Meanwhile, the other end 617 is set to be movable (in other words, to be released) in the horizontal direction without engaging with the cover portion 711 of the second fixation frame 7. Therefore, the plate-shaped portion 61 is set to be in a state of a so-called cantilever.

Operation of Plate-Shaped Portion 61 when Projector 1 Drops

A description will be given of an operation of the plate-shaped portion 61 in a case where the projector 1 is dropped in a predetermined direction in a state where the projector 1 is assembled (complete body of the projector 1) including assembling in which the cooling mechanism 4 is fixed to the lower case 21.

Regarding a drop direction (direction in which an impact is applied) of the projector 1 in the present embodiment, it is assumed that the projector 1 is dropped in a direction which is substantially perpendicular to the surface of the plate-shaped portion 61 as a predetermined direction. In other words, a drop is performed so that the air suction port 52 of the cooling fan 5 is set to be a lower side (the right side of the projector 1 (external housing 2) is a lower side) on the assumption that the rotation center axis A of the cooling fan 5 is in a vertical direction (perpendicular direction). That is, the predetermined drop direction in the present embodiment is set to be a substantially extending direction of the rotation center axis A of the cooling fan 5 and a direction substantially perpendicular to the surface of the plate-shaped portion 61. When a drop is performed in such a direction, the extension portion 613 (one end 611) is fixed by the second screw SC2, and the plate-shaped portion 61 having fixed the cooling fan 5 is bent in a drop direction to thereby reduce an impact applied to the cooling fan 5. After the drop, the plate-shaped portion 61 can be returned to its original position by its own flexibility.

According to the projector 1 of the present embodiment, the following effects are obtained.

In the projector 1 as an electronic apparatus of the present embodiment, the plate-shaped portion 61 having fixed the cooling fan 5 can be configured to have a structure of a substantially cantilever. When the projector drops in a drop direction which is substantially perpendicular to the plate-shaped portion 61 as a predetermined drop direction (direction in which an impact is applied), the plate-shaped portion 61 is bent in the drop direction, and thus it is possible to absorb an impact applied to the cooling fan 5 by the drop. Thereby, it is possible to realize the projector 1 with a reduced influence on the cooling fan 5 due to an impact of a drop in the projector 1 including the cooling fan 5.

The cooling fan 5 of the present embodiment is fixed to the plate-shaped portion 61 by the first screw SC1 which is inserted in a direction substantially parallel to the rotation center axis A. Thereby, an impact of a drop is directly propagated to the plate-shaped portion 61, and the plate-shaped portion 61 is shaken due to an impact, and thus it is possible to reduce an influence on the cooling fan 5 due to the impact of the drop.

In the projector 1 of the present embodiment, the plurality of hole portions 614 of the extension portion 613 are installed along the one end 611 of the plate-shaped portion 61, and thus there is a tendency for the plate-shaped portion 61 to be further bent, which makes it easier to absorb an impact of a drop. Therefore, it is possible to further reduce an influence on the cooling fan 5 due to the impact.

In the projector 1 of the present embodiment, a fixation frame (first fixation frame 6) constitutes a portion of a duct (first duct 621, second duct 622, third duct 623), and thus it is possible to cool a component generating heat by making the air suctioned by the cooling fan 5 flow.

Meanwhile, the invention is not limited to the above-described embodiment, and various changes, improvements, and the like can be made without departing from the scope of the invention. A modification example will be described below.

In the embodiment, the invention is applied to the projector 1 as an electronic apparatus. However, the invention is not limited thereto, and the invention can also be applied to an electronic apparatus including a cooling fan other than the projector 1.

In the embodiment, a sirocco fan (cooling fan 5) to be used has a specification requiring suctioning from a sub-air suction port (air suction port 53), and thus the second fixation frame 7 is used. On the other hand, in the case of a specification that does not require a sub-air suction port, a second fixation frame may not be used.

In the embodiment, it is assumed that the air suction port 52 of the cooling fan 5 is installed at a corner portion on the right front side of the projector 1 (lower case 21), but the air suction port 52 may be installed at another position. In other words, for example, a configuration may be adopted in which the air suction port 52 is installed on the lower side of the lower case 21 and a direction of the rotation center axis A of the cooling fan 5 substantially conforms to a vertical direction in a posture in which the projector 1 is installed on a desk.

The shape of the plate-shaped portion 61 constituting the first fixation frame 6 of the embodiment, the number of ducts and the shape of the duct of the duct component 62, and the like can be appropriately modified.

In the projector 1 of the embodiment, a discharge lamp is used. As the discharge lamp, various types of lamps, such as, a metal halide lamp, a high pressure mercury lamp, and an ultrahigh pressure mercury lamp, which emit light with high luminance can be used.

In the projector 1 of the embodiment, the liquid crystal panel 351 is used as an optical modulation device. Meanwhile, a transmissive liquid crystal panel or a reflective liquid crystal panel can be used as the liquid crystal panel 351.

In the projector 1 of the embodiment, the liquid crystal panel 351 is used as an optical modulation device. However, the invention is not limited thereto, and another type of optical modulation device such as a micromirror type optical modulation device which is different from a liquid crystal panel can be used. Meanwhile, for example, a digital micromirror device (DMD) can be used as the micromirror type optical modulation device.

### CROSS REFERENCE TO RELATED APPLICATIONS

This application claims priority to Japanese Patent Application No. 2014-230439 filed on Nov. 13, 2014, the entire contents of which are incorporated by reference herein.

What is claimed is:

1. An electronic apparatus comprising:
a cooling fan;
a fixation frame that fixes the cooling fan; and
an external housing that fixes the fixation frame,
wherein the fixation frame includes a plate-shaped portion that fixes the cooling fan, and
wherein the plate-shaped portion has one end fixed to the external housing and the other end which is released, is installed so as to be substantially perpendicular to an extending direction of a rotation center axis of the cooling fan, and has flexibility that the plate-shaped portion is bent in a substantially extending direction of the rotation center axis when an impact is applied to the electronic apparatus.

2. The electronic apparatus according to claim 1, wherein the cooling fan is fixed to the plate-shaped portion by a first screw which is inserted in a direction substantially parallel to the rotation center axis.

3. The electronic apparatus according to claim 1,
wherein the plate-shaped portion has an extension portion extending from the one end, and
wherein the extension portion includes a plurality of hole portions for performing fixation to the external housing by a screw along the one end.

4. The electronic apparatus according to claim 2,
wherein the plate-shaped portion has an extension portion extending from the one end, and
wherein the extension portion includes a plurality of hole portions for performing fixation to the external housing by a screw along the one end.

5. The electronic apparatus according to claim 1, wherein the fixation frame constitutes a portion of a duct that makes air suctioned by the cooling fan flow.

6. The electronic apparatus according to claim 1, further comprising:
a light source device that emits light;
an optical modulation device that modulates the light emitted from the light source device in accordance with image information; and
a projection lens that projects the light modulated by the optical modulation device.

7. The electronic apparatus according to claim 2, further comprising:
a light source device that emits light;
an optical modulation device that modulates the light emitted from the light source device in accordance with image information; and
a projection lens that projects the light modulated by the optical modulation device.

8. The electronic apparatus according to claim 3, further comprising:
a light source device that emits light;
an optical modulation device that modulates the light emitted from the light source device in accordance with image information; and
a projection lens that projects the light modulated by the optical modulation device.

9. The electronic apparatus according to claim 4, further comprising:
a light source device that emits light;
an optical modulation device that modulates the light emitted from the light source device in accordance with image information; and
a projection lens that projects the light modulated by the optical modulation device.

10. The electronic apparatus according to claim 5, further comprising:
a light source device that emits light;
an optical modulation device that modulates the light emitted from the light source device in accordance with image information; and
a projection lens that projects the light modulated by the optical modulation device.
